(19) United States
(12) Patent Application Publication
(10) Pub. No.: US 2013/0033337 A1
(43) Pub. Date: Feb. 7, 2013

(54) ACOUSTIC WAVE FILTER

(71) Applicants: Tokihiro NISHIHARA, Tokyo (JP); Shinji TANIGUCHI, Tokyo (JP); Masanori UEDA, Tokyo (JP)

(72) Inventors: Tokihiro NISHIHARA, Tokyo (JP); Shinji TANIGUCHI, Tokyo (JP); Masanori UEDA, Tokyo (JP)

(73) Assignee: TAIYO YUDEN CO., LTD., Tokyo (JP)

(21) Appl. No.: 13/556,881

(22) Filed: Jul. 24, 2012

(30) Foreign Application Priority Data
Aug. 3, 2011 (JP) 2011-170500

(51) Int. Cl. H03H 9/54; H03H 9/70

(52) U.S. Cl. 333/133; 333/187; 333/188; 333/189

(57) ABSTRACT

An acoustic wave filter including piezoelectric thin film resonators, in which at least two of the piezoelectric thin film resonators including: a substrate; a piezoelectric film located on the substrate; a lower electrode and an upper electrode located across at least a part of the piezoelectric film; a mass load film for a frequency control located in a resonance region where the lower electrode and the upper electrode face each other, and having a shape different from that of the resonance region; and a temperature compensation film having a temperature coefficient of an elastic constant opposite in sign to that of the piezoelectric film, at least a part of the temperature compensation film being located between the lower electrode and the upper electrode in the resonance region, and areas of mass load films of said at least two of the piezoelectric thin film resonators are different from each other.

### CROSS-REFERENCE TO RELATED APPLICATION

This application is based upon and claims the benefit of priority of the prior Japanese Patent Application No. 2011-170500, filed on Aug. 3, 2011, the entire contents of which are incorporated herein by reference.

### FIELD

A certain aspect of the present invention relates to an acoustic wave filter.

### BACKGROUND

A BAW filter which uses Bulk Acoustic Wave (BAW) has been known as a filter for wireless devices such as mobile phones. A BAW filter is composed of piezoelectric thin film resonators, and each piezoelectric thin film resonator has a structure in which an upper electrode and a lower electrode face each other across a piezoelectric film. The resonance frequency of a piezoelectric thin film resonator is determined by constitutional materials and the film thickness of a region where the upper electrode and the lower electrode face each other (hereinafter, referred to as a resonance region).

To make resonance frequencies of piezoelectric thin film resonators have different values, there has been known techniques to form a mass load film in the resonance region as disclosed in Japanese Patent Application Publication No. 2002-335141, Japanese Unexamined Patent Application Publication (Translation of PCT Application) Nos. 2002-515667 and 2007-535279 for example. It is possible to change a resonance frequency arbitrarily by changing a pattern or a thickness of a mass load film. In addition, to suppress the frequency shift due to a temperature change, there has been known techniques to form a temperature compensation film in the resonance region as disclosed in Japanese Patent Application Publication No. 58-137317 for example. The temperature compensation film is formed between piezoelectric films, and has a temperature coefficient of the resonance frequency which is opposite in sign to that of the piezoelectric film.

In an acoustic wave filter which uses a temperature compensation film in a piezoelectric thin film resonator, a temperature coefficient of frequency TCF and an effective electromechanical coupling coefficient K²_{eff} which is a coefficient proportional to a fractional bandwidth of a filter have a trade-off relation. Therefore, since K²_{eff} decreases and the fractional bandwidth becomes small if trying to increase the TCF, there is a problem that it is difficult to obtain a wideband filter. On the other hand, if trying to widen the bandwidth forcedly, there is a problem that the matching of a filter is degraded.

Moreover, in a conventional acoustic wave filter, there is a problem that, due to the insertion of the temperature compensation film in the piezoelectric film, the dependence of the resonance frequency on the film thickness becomes high compared to a case where the temperature compensation film is formed in a surface layer, and that a variability of resonance frequency is increased.

### SUMMARY OF THE INVENTION

According to an aspect of the present invention, there is provided an acoustic wave filter including piezoelectric thin film resonators, wherein at least two of the piezoelectric thin film resonators includes: a substrate; a piezoelectric film located on the substrate; a lower electrode and an upper electrode located across at least a part of the piezoelectric film; a mass load film for a frequency control which is located in a resonance region in which the lower electrode and the upper electrode face each other, and has a shape different from that of the resonance region; and a temperature compensation film that has a temperature coefficient of an elastic constant that is opposite in sign to a temperature coefficient of an elastic constant of the piezoelectric film, at least a part of the temperature compensation film being located between the lower electrode and the upper electrode in the resonance region, and areas of mass load films of said at least two of the piezoelectric thin film resonators are different from each other.

According to another aspect of the present invention, there is provided a duplexer including a transmission filter and a reception filter, wherein at least one of the transmission filter and the reception filter is provided with the above mentioned acoustic wave filter.

### BRIEF DESCRIPTION OF THE DRAWINGS

FIG. 1 is a diagram illustrating a circuit configuration of acoustic wave filters in accordance with a comparative example and a first embodiment;

FIGS. 2A through 2C are schematic views illustrating a structure of a piezoelectric thin film resonator in accordance with the comparative example;

FIG. 3 is a graph illustrating a relation between a film thickness of a temperature compensation film and a temperature coefficient of frequency (TCF) and an effective electromechanical coupling coefficient (K²_{eff});

FIG. 4 is a graph illustrating a relation between the temperature coefficient of frequency (TCF) and a fractional bandwidth;

FIG. 5 is a table showing resonance frequencies of piezoelectric thin film resonators in acoustic wave filters in accordance with the comparative example and first through third embodiments;

FIGS. 6A through 6C are graphs illustrating band characteristics of acoustic wave filters in accordance with the comparative example;

FIGS. 7A through 7C are schematic views illustrating a structure of a piezoelectric thin film resonator in accordance with the first embodiment;

FIGS. 8A through 8F are schematic views illustrating a configuration of a mass load film;

FIGS. 9A and 9B are tables showing a relation between a coverage rate of the mass load film and a resonance frequency;

FIGS. 10A through 10C are graphs illustrating band characteristics of acoustic wave filters in accordance with the first embodiment;

FIG. 11 is a diagram illustrating a circuit configuration of an acoustic wave filter in accordance with a second embodiment;

FIGS. 12A through 12C are graphs showing band characteristics of acoustic wave filters in accordance with the second embodiment;

FIGS. 13A through 13C are graphs showing band characteristics of acoustic wave filters in accordance with the second embodiment;

FIGS. 14A through 14C are graphs showing band characteristics of acoustic wave filters in accordance with a third embodiment;

FIGS. 15A through 15D are schematic views illustrating a structure of a piezoelectric thin film resonator in accordance with a modified embodiment of first through third embodiments;

FIG. 16 is a diagram illustrating a circuit configuration of an acoustic wave filter in accordance with the modified embodiment of first through third embodiment; and

FIG. 17 is a diagram illustrating a circuit configuration of a duplexer using the acoustic wave filter in accordance with the first through third embodiments.

### DETAILED DESCRIPTION

### Comparative Example

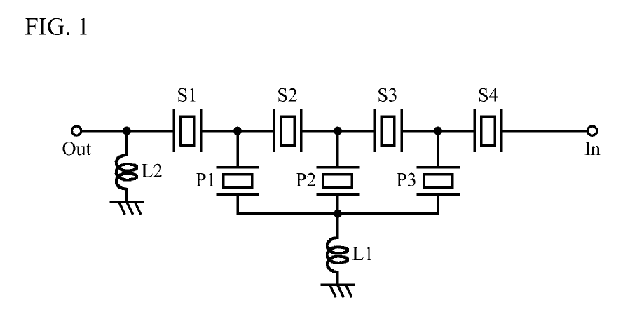

FIG. 1 is a circuit diagram illustrating a configuration of acoustic wave filters in accordance with a comparative example and a first embodiment. The acoustic wave filter is a ladder-type filter including series resonators S1 through S4, parallel resonators P1 through P3 and inductors L1 and L2. Series resonator S1 through S4 and parallel resonators P1 through P3 are piezoelectric thin film resonators. Series resonator S1 through S4 are connected in series between an output terminal Out and an input terminal In. One end of the parallel resonator P1 is connected between series resonators S1 and S2, one end of the parallel resonator P2 is connected between series resonators S2 and S3, and one end of the parallel resonator P3 is connected between series resonators S3 and S4. The other ends of parallel resonators P1 through P3 are unified, and connected to ground via the inductor L1. The inductor L2, one end of which is connected to ground, is connected between the output terminal Out and the series resonator S1.

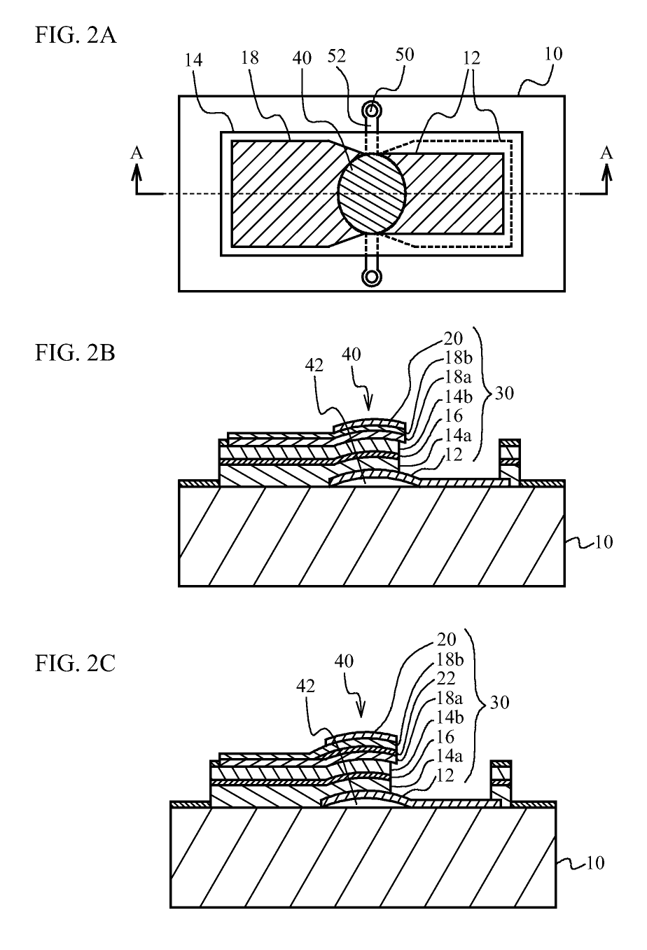

FIGS. 2A through 2C are schematic views illustrating a structure of the piezoelectric thin film resonator constituting the acoustic wave filter in accordance with the comparative example. FIG. 2A is a top schematic view of the piezoelectric thin film resonator, FIG. 2B is a schematic cross-sectional view of series resonators S1 through S4, and FIG. 2C is a schematic cross-sectional view of parallel resonators P1 through P3. FIG. 2A is a diagram common to series resonators S1 through S4 and parallel resonators P1 through P3, and FIGS. 2B and 2C are schematic cross-sectional views taken along line A-A of FIG. 2A.

As illustrated in FIG. 2B, series resonators S1 through S4 have a structure in which a lower electrode 12, a first piezoelectric film 14a, a temperature compensation film 16, a second piezoelectric film 14b, an upper electrode 18 (including a ruthenium (Ru) layer 18a and a chrome (Cr) layer 18b), and a frequency adjusting film 20 are stacked on a substrate 10 in this order (hereinafter, referred to as a multilayered film 30). A region where the upper electrode 18 and the lower electrode 12 face each other across piezoelectric films (the first piezoelectric film 14a and the second piezoelectric film 14b) is a resonance region 40. In the resonance region 40, the lower electrode 12 is formed to curve in a convex shape to the upper direction, and accordingly a dome-shaped space 42 is formed between the substrate 10 and the lower electrode 12. In addition, a part of each of the first piezoelectric film 14a, the temperature compensation film 16 and the second piezoelectric film 14b is removed by etching, and at least a part of each outer periphery of three layers described above is formed so as to be located in the inner side of the upper electrode 18.

As illustrated in FIG. 2C, parallel resonators P1 through P3 basically have a same structure as series resonators S1 through S4, but are different in that a mass load film (hereinafter, a first mass load film 22) is formed between the Ru layer 18a and the Cr layer 18b in the upper electrode 18. Resonance frequencies of parallel resonators P1 through P3 are shifted to the low frequency side by including the first mass load film 22 compared to those of series resonators S1 through S4. To shift resonance frequencies of parallel resonators P1 through P3 to the low frequency side, the thickness of a certain layer in the multilayered film 30 may be made to be larger than that of the same layer in series resonators S1 through S4 instead of forming the first mass load film 22.

As illustrated in FIG. 2A, an etching medium introduction hole 50 is provided to a surface of the lower electrode 12 locating in the vicinity of the resonance region 40. Moreover, an etching medium introduction path 52 is formed between the etching medium introduction hole 50 and the space 42. In addition, the lower electrode 12 of which the entire part is illustrated with a dashed line has a structure in which a part of it (hatched part) is exposed from apertures of piezoelectric films (14a, 14b).

It is possible to use silicon (Si) for the substrate 10, and is also possible to use glass and ceramics besides silicon. In addition, an electrode film in which chrome (Cr) and ruthenium (Ru) are stacked in this order from the substrate 10 side may be used as the lower electrode 12, and an electrode film in which ruthenium (Ru) and chrome (Cr) are stacked in this order from the substrate 10 side may be used as the upper electrode 18. However, for the lower electrode 12 and the upper electrode 18, in addition to above examples, aluminum (Al), copper (Cu), chrome (Cr), molybdenum (Mo), tungsten (W), tantalum (Ta), platinum (Pt), ruthenium (Ru), rhodium (Rh), iridium (Ir), titanium (Ti) and the like may be used in combination. In addition, the electrode film may have a single-layer structure instead of a double-layer structure.

In addition, aluminum nitride (AlN) may be used for the first piezoelectric film 14a and the second piezoelectric film 14b, and in addition to this, piezoelectric materials such as zinc oxide (ZnO), lead zirconate titanate (PZT), and lead titanate (PbTiO₃) may be used. The temperature compensation film 16 is a film having a temperature coefficient of an elastic constant which is opposite in sign to those of piezoelectric films (14a, 14b). Silicon dioxide (SiO₂) may be used for the temperature compensation film 16 for example, and in addition to silicon dioxide, a film which includes oxide silicon mainly and also includes other elements may be used. Silicon dioxide (SiO₂) may be used for the frequency adjusting film 20 for example, and in addition to silicon dioxide, other insulating materials such as aluminum nitride (AlN) may be used. Titanium (Ti) may be used for the first mass load film 22 used in parallel resonators P1 through P3, and in addition to titanium, aluminum (Al), copper (Cu), chrome (Cr), molybdenum (Mo), tungsten (W), tantalum (Ta), platinum (Pt), ruthenium (Ru), rhodium (Rh), iridium (Ir), silicon dioxide (SiO₂) and the like may be used.

The multilayered film 30 described above can be formed by forming a film by the sputtering method or the like and then patterning the film into a desired shape by the photolithographic technique and the etching technique for example. The patterning of the multilayered film 30 can also be executed by the liftoff technique. The etching of outer peripheries of the first piezoelectric film 14a, the temperature compensation film 16, and the second piezoelectric film 14b can be executed by the wet etching using the upper electrode 18 as a mask for example.

The dome-shaped space 42 located below the lower electrode 12 can be formed by removing a sacrifice layer (not illustrated), which is preliminarily provided before forming the lower electrode 12, after forming the above described multilayered film 30. Materials such as MgO, ZnO, Ge and SiO₂ which can be easily dissolved by etching liquid or etching gas can be used for the sacrifice layer, and the sacrifice layer can be formed by the sputtering method, the evaporation method or the like for example. The sacrifice layer is preliminarily formed into a desired shape (the shape of the space 42) by the photolithographic technique and the etching technique. After the formation of the multilayered film 30, the sacrifice layer is removed by introducing the etching medium beneath the lower electrode 12 via the etching medium introduction hole 50 and the etching medium introduction path 52 that are formed in the lower electrode 12.

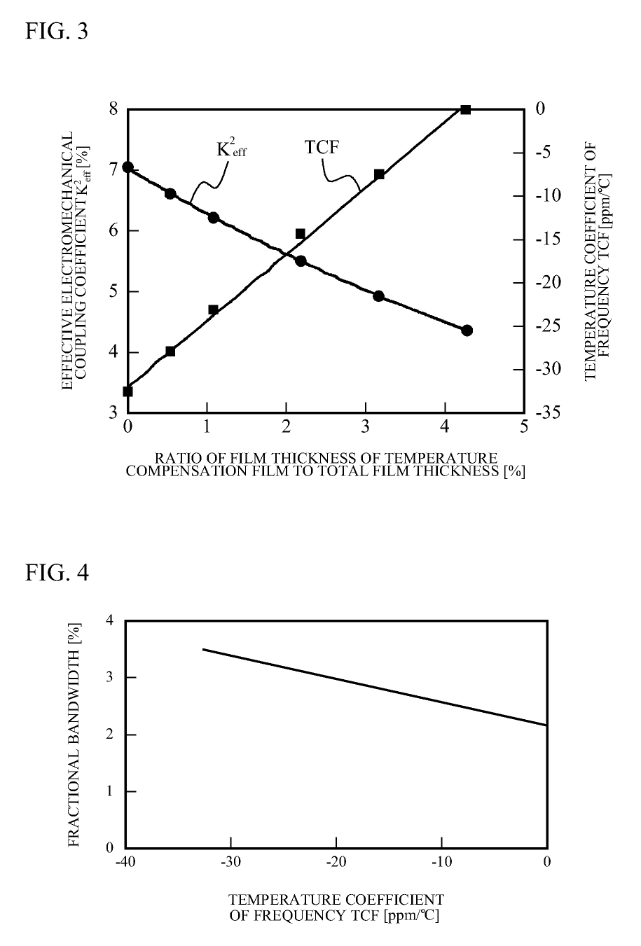

FIG. 3 is a graph of the temperature coefficient of frequency (TCF) and the effective electromechanical coupling coefficient (K²_{eff}) versus the film thickness of the temperature compensation film 16 in the acoustic wave filter in which the temperature compensation film 16 is provided between piezoelectric films (14a, 14b). A simulation is run under the assumption that materials and film thicknesses of stacked films are as follows from the substrate 10 side: the lower electrode 12 is made of Cr with a thickness of 100 nm and Ru with a thickness of 200 nm, the first piezoelectric film 14a is made of AlN with a thickness of 630 nm, the temperature compensation film 16 is made of SiO₂, the second piezoelectric film 14b is made of AlN with a thickness of 630 nm, and the upper electrode 18 is made of Ru with a thickness of 230 nm and Cr with a thickness of 35 nm. As illustrated, the TCF [ppm/° C.] and the K²_{eff} [%] have a trade-off relation, and if the film thickness of the temperature compensation film 16 (SiO₂) is increased, the value of the TCF is improved (the absolute value decreases), but the value of the K²_{eff} decreases.

FIG. 4 is a graph showing a relation between the temperature coefficient of frequency TCF and the fractional bandwidth. Here, there has been known a relation that K²_{eff} which is almost two times of the fractional bandwidth is necessary to obtain a ladder filter having a desired fractional bandwidth [%] (=bandwidth*100/center frequency). Assuming that the value of the TCF is T [ppm/° C.], the fractional bandwidth is expressed with a relational expression “fractional bandwidth [%]=−0.041*T+2.17”. FIG. 4 is a graph representing the above relational expression. According to FIG. 3 and FIG. 4, if the film thickness of temperature compensation film 16 is increased to improve the value of the TCF, K²_{eff} decreases, and as a result, the fractional bandwidth of the filter becomes small.

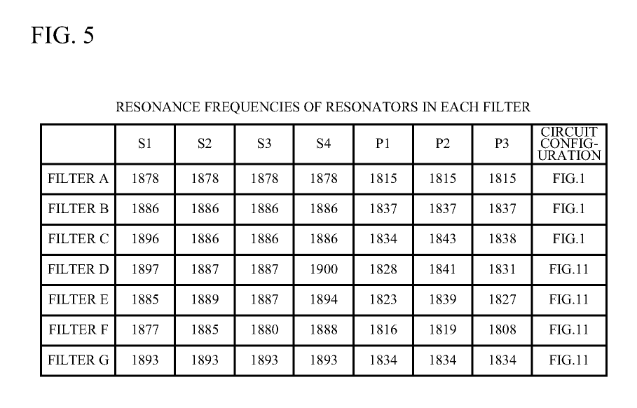

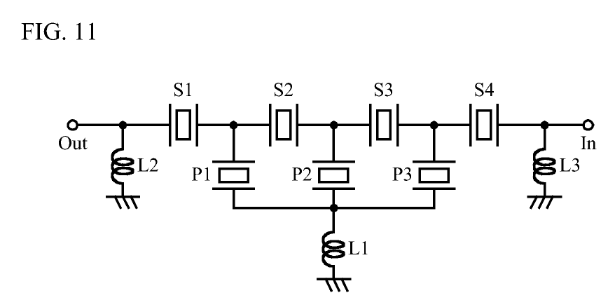

FIG. 5 is a table showing resonance frequencies of piezoelectric thin film resonators in acoustic wave filters in accordance with the comparative example and first through third embodiments. Here, a description will be given by using a transmission filter for Band 2 (transmission band:1850-1910 MHz, reception band:1930-1990 MHz) as an example. Filters A, B and G are acoustic wave filters in accordance with the comparative example (FIG. 1), a filter C is an acoustic wave filter in accordance with the first embodiment (FIG. 1), and filters D through F are acoustic wave filters in accordance with a second embodiment (FIG. 11). However, filters A through G have a commonality in that each of filters includes four series resonators S1 through S4 and three parallel resonators P1 through P3. In addition, in filters A through G, piezoelectric thin film resonators of filters B through G have a structure in which the temperature compensation film 16 is inserted between piezoelectric films (14a, 14b) as illustrated in FIG. 2. On the other hand, the piezoelectric thin film resonator of the filter A has a structure in which the temperature compensation film 16 is not inserted into the piezoelectric film but is provided to the surface layer (an illustration of the configuration of the filter A is omitted).

In acoustic wave filters (filters A, B and G) in accordance with the comparative example, resonance frequencies of series resonators S1 through S4 are set to be equal to each other (A:1878 MHz, B:1886 MHz, G:1893 MHz), and resonance frequencies of parallel resonators P1 through P3 are also set to be equal to each other (A:1815 MHz, B:1837 MHz, G:1834 MHz). In other words, in acoustic wave filters in accordance with the comparative example, resonance frequencies of series resonators S1 through S4 are equal to the average of those, and resonance frequencies of parallel resonators P1 through P3 are equal to the average of those.

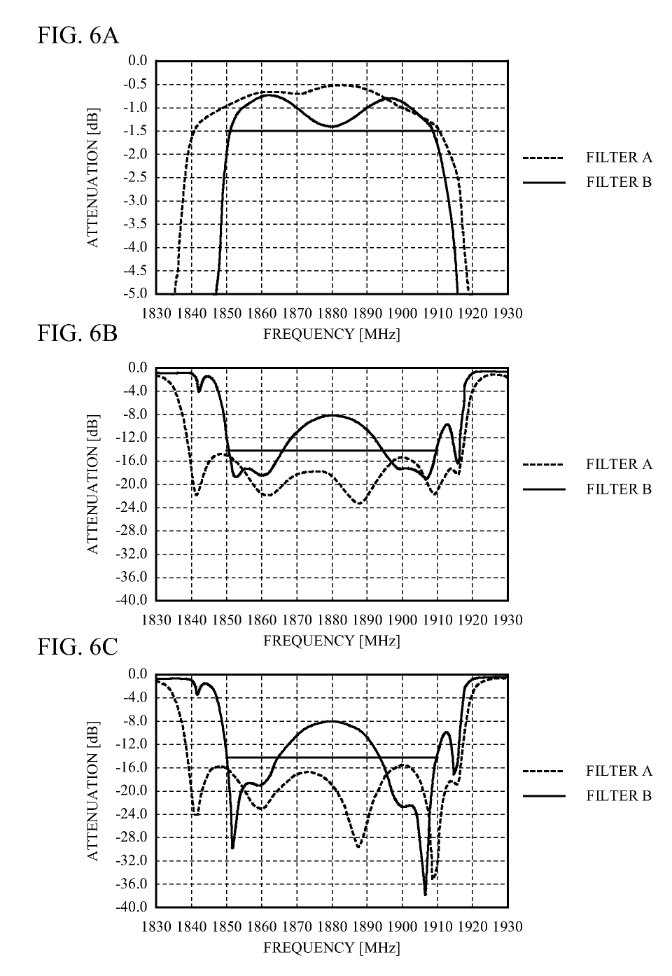

FIGS. 6A through 6C are graphs showing a comparison of band characteristics between filters A and B of acoustic wave filters in accordance with the comparative example. A simulation is run under the assumption that materials and film thicknesses of stacked films of the filter A are as follows from the substrate 10 side: the lower electrode 12 is made of Cr with a thickness of 100 nm and Ru with a thickness of 230 nm, the piezoelectric film 14 is made of AlN with a thickness of 1300 nm, the upper electrode 18 is made of Ru (numerical symbol 18a) with a thickness of 230 nm and Cr (numerical symbol 18b) with a thickness of 30 nm, the first mass load film 22 (only parallel resonators P1 through P3 include) is made of Ti with a thickness of 110 nm, and the frequency adjusting film 20 is made of SiO₂ with a thickness of 50 nm.

A simulation is run under the assumption that materials and film thicknesses of stacked films of the filter B are as follows from the substrate 10 side: the lower electrode 12 is made of Cr with a thickness of 85 nm and Ru with a thickness of 195 nm, the first piezoelectric film 14a is made of AlN with a thickness of 550 nm, the temperature compensation film 16 is made of SiO₂ with a thickness of 70 nm, the second piezoelectric film is made of AlN with a thickness of 550 nm, the upper electrode 18 is made of Ru with a thickness of 195 nm and Cr with a thickness of 25 nm, the first mass load film 22 (only parallel resonators P1 through P3 include) is made of Ti with a thickness of 80 nm, and the frequency adjusting film 20 is made of SiO₂ with a thickness of 50 nm. The TCF of the filter is made to be substantively 0 by making the thickness of the temperature compensation film 16 (SiO₂) be 70 nm.

FIG. 6A illustrates bandpass characteristics of filters, FIG. 6B illustrates return loss characteristics at the output terminal, and FIG. 6C illustrates return loss characteristics at the input terminal. Characteristics of the filter A is illustrated by dashed lines, and characteristics of the filter B is illustrated by solid lines. A horizontal line illustrated in the center area of the graph represents the passband (1850-1910 MHz) and an attenuation level required in the Band 2 (same applies to graphs hereinafter). In the filter B in which the temperature compensation film 16 is inserted, compared to the filter A which does not include the temperature compensation film 16, the matching states at the input terminal and the output terminal are bad, and the bandwidth is narrow. The value of K²_{eff} in the filter A is from 6.7% to 7.3%, and the value of K²_{eff} in the filter B is from 4.4% to 4.6%. As described above, in the filter B, compared to the filter A, the value of K²_{eff} decreases, and as a result, the bandwidth becomes narrow.

As described above, in the acoustic wave filter in accordance with the comparative example, the TCF is improved by inserting the temperature compensation film 16 between piezoelectric films (14a, 14b) of the resonator which constitutes a ladder filter, but K²_{eff} decreases and the bandwidth becomes narrow. On the other hand, if trying to widen the bandwidth forcedly, the matching of the filter is degraded.

In addition, when the temperature compensation film 16 is located between piezoelectric films (14a, 14b), the dependence of the resonance frequency on the film thickness becomes high compared to the case where the temperature compensation film 16 is located in the surface layer. For example, if the temperature compensation film is provided to the surface layer like the filter A, the changing amount of resonance frequency to a film thickness variation of 1% is 0.007%. On the other hand, if the temperature compensation film is located between piezoelectric films, the above changing amount is greatly increased and becomes 0.14%. As a result, the variability of resonance frequency increases, and more strict frequency control becomes necessary.

In embodiments hereinafter, descriptions will be given of a configuration capable of achieving the bandwidth widening and improvement of the matching of the acoustic wave filter, and suppressing the variability of resonance frequency.

### First Embodiment

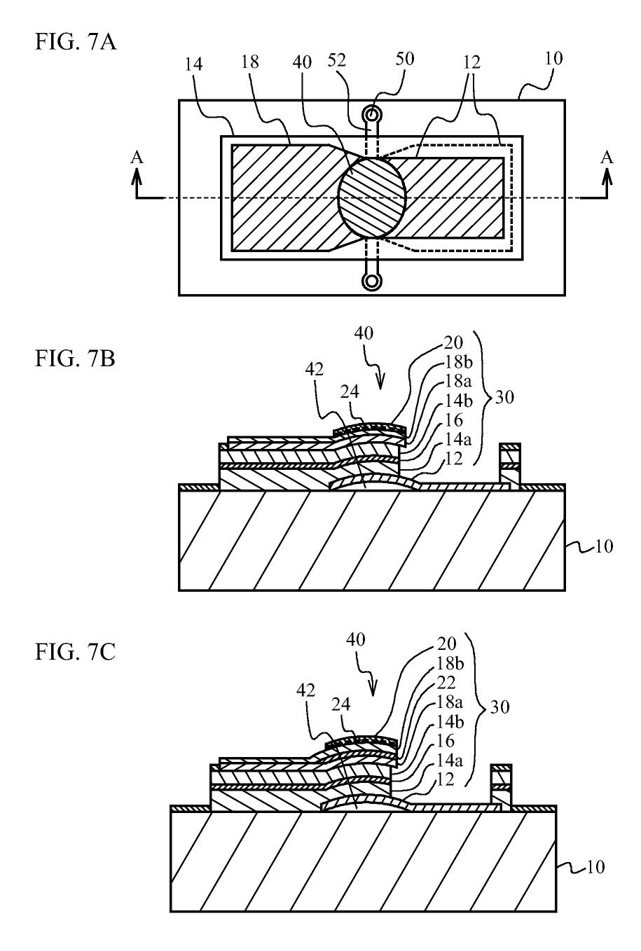

FIGS. 7A through 7C are schematic views illustrating a structure of a piezoelectric thin film resonator in the acoustic wave filter in accordance with the first embodiment, and correspond to FIGS. 2A through 2C of the comparative example respectively. The structure of the piezoelectric thin film resonator in accordance with the first embodiment is basically the same as that of the comparative example, but is different in that a mass load film for the frequency control (hereinafter, a second mass load film 24) is formed in the resonance region 40 located between the upper electrode 18 and the frequency adjusting film 20. The second mass load film 24 is used for making resonance frequencies of resonators constituting the acoustic wave filter have different values as described later. In acoustic wave filters (filters A, B and G) in accordance with the comparative example, the second mass load film 24 is not used.

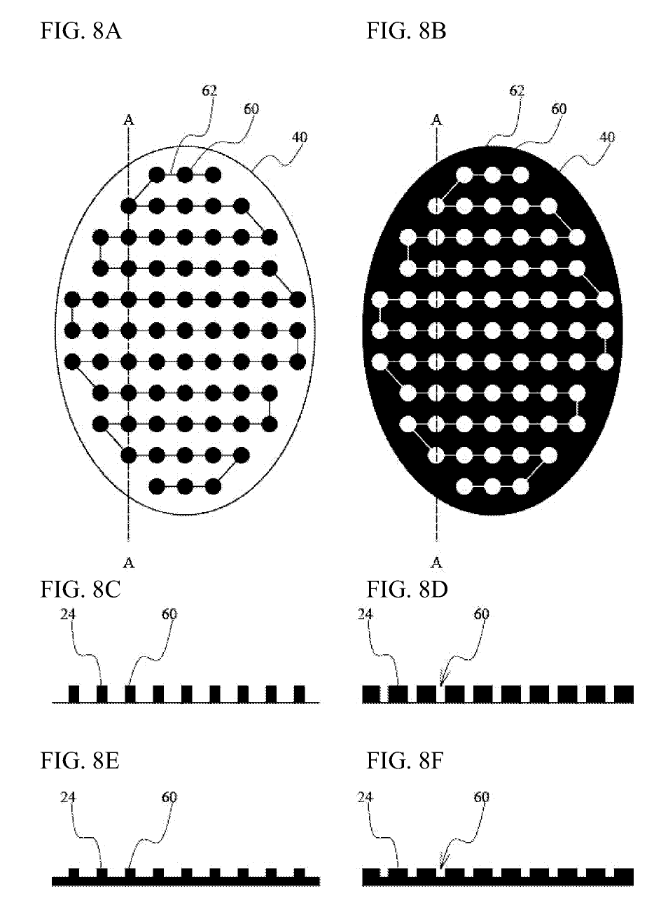

FIGS. 8A through 8F are schematic views illustrating a detail structure of the second mass load film 24. FIGS. 8A and 8B are top schematic views, and FIGS. 8C through 8F are schematic cross-sectional views. As illustrated in FIGS. 8A and 8B, patterns (hereinafter, referred to as dot patterns 60) each of which has the same shape and same size are formed in the second mass load film 24 at equal distance, and dot patterns 60 are connected each other by patterns each of which has a smaller width (hereinafter, referred to as line patterns 62). FIG. 8C is a schematic cross-sectional view taken along line A-A of FIG. 8A, and dot patterns 60 and line patterns 62 are formed to have a convex structure. FIG. 8D is a schematic cross-sectional view taken along line A-A of FIG. 8B, and dot patterns 60 and line patterns 62 are formed to have a concave structure. In addition, FIGS. 8E and 8F are modified embodiments corresponding to FIGS. 8C and 8D respectively, and the thickness of the concave portion in the second mass load film 24 is made larger. Patterns formed in the second mass load film 24 may have various shapes other than above described ones.

In the present embodiment, titanium (Ti) is used for the second mass load film 24, but in addition to this, aluminum (Al), copper (Cu), chrome (Cr), molybdenum (Mo), tungsten (W), tantalum (Ta), platinum (Pt), ruthenium (Ru), rhodium (Rh), iridium (Ir), silicon dioxide (SiO₂) and the like may be used. When executing the patterning of the second mass load film 24, a desired pattern can be formed by the photolithographic technique and the etching technique for example. Moreover, when it is difficult to execute the etching, the patterning of the second mass load film 24 may be executed by the liftoff technique.

In the first embodiment, it is possible to make resonance frequencies have different values from each other by changing the area (coverage rate) of the mass load film in each resonator by patterning the second mass load film 24. Hereinafter, a detail description will be given of this point.

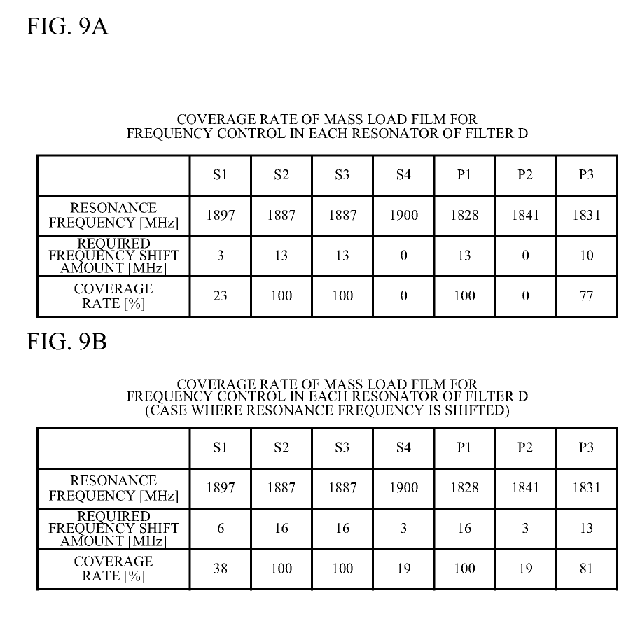

FIGS. 9A and 9B are tables showing a relation between the coverage rate of the mass load film and the resonance frequency. FIG. 9A is an example of a case where the resonance frequency is as designed, and FIG. 9B is an example of a case where the resonance frequency is shifted from the designed value as the film thickness is different from the designed value. Here, a description will be given by using the filter D in accordance with the second embodiment described later (see FIG. 5 and FIG. 11) as an example. The configuration of the filter D is basically the same as that of the filter C in accordance with the first embodiment, and a relation between the coverage rate and the resonance frequency illustrated in FIGS. 9A and 9B are also applied to the filter C. Materials and film thicknesses of stacked films of the filter D are as follows from the substrate 10 side: the lower electrode 12 is made of Cr with a thickness of 85 nm and Ru with a thickness of 195 nm, the first piezoelectric film 14a is made of AlN with a thickness of 550 nm, the temperature compensation film 16 is made of SiO₂ with a thickness of 70 nm, the second piezoelectric film 14b is made of AlN with a thickness of 550 nm, the upper electrode 18 is made of Ru with a thickness of 195 nm and Cr with a thickness of 25 nm, the first mass load film 22 (only parallel resonators P1 through P3 include) is made of Ti with a thickness of 95 nm, the second mass load film 24 is made of Ti (the film thickness is described later), and the frequency adjusting film 20 is made of SiO₂ with a thickness of 10 nm. These are same as the structure of the multilayered film 30 of the filter C in accordance with the first embodiment.

In FIGS. 9A and 9B, a coverage rate of 0% means a state where the second mass load film 24 is not formed at all, and a coverage rate of 100% means a state where the second mass load film 24 is formed but is not patterned. As illustrated in FIG. 9A, in respective resonators having the highest resonance frequency (S4, P2) in series resonators S1 through S4 and parallel resonators P1 through P3, the coverage rate of the second mass load film 24 is 0%. Respective differences from frequencies of resonators S4 and P2 are required frequency shift amount. In the present embodiment, it is necessary to shift the frequency by 13 MHz at maximum. As the frequency shift amount to the film thickness of the second mass load film 24 (Ti) is 0.63 MHz/nm, the required film thickness becomes 21 nm. As the frequency is shifted linearly against the coverage rate of the second mass load film 24 for the frequency control, the coverage rate in each resonator is calculated as shown in FIG. 9A.

In addition, as illustrated in FIG. 9B, when the resonance frequency of the resonator is shifted from the designed value (in the present embodiment, assume that it is higher than the desired value by 3 MHz), the required frequency shift amount becomes the value calculated by adding 3 MHz to that of FIG. 9A, and a maximum shift amount becomes 16 MHz. At this time, the film thickness necessary to the second mass load film 24 becomes 25 nm, and the coverage rate in each resonator is calculated as shown in FIG. 9B.

In the acoustic wave filter in accordance with the first embodiment, using the above described relation, it is possible to change the resonance frequency of each resonator arbitrarily by changing the coverage rate (area) by executing the patterning to the second mass load film 24. Here, when the coverage rate is small (e.g. less than 50%), it is preferable to use the convex pattern illustrated in FIGS. 8A, 8C and 8E, and when the coverage rate is large (e.g. equal to or more than 50%), it is preferable to use the concave pattern illustrated in FIGS. 8B, 8D and 8F.

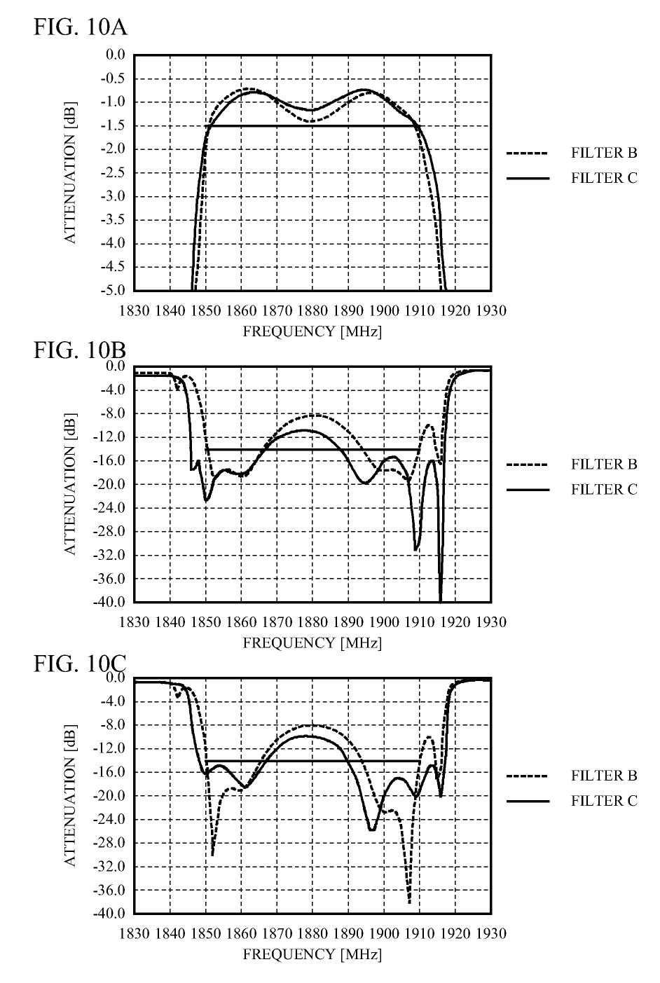

FIGS. 10A through 10C are graphs illustrating a comparison of band characteristics between the acoustic wave filter in accordance with the first embodiment (filter C) and one in accordance with the comparative example (filter B). Materials and film thicknesses of stacked films of the filter B are the same as those described in the comparative example, and materials and film thicknesses of stacked films of the filter C are the same as those of the filter D. As illustrated in FIG. 5, the filter C in accordance with the first embodiment has a configuration in which the resonance frequency of S1 out of series resonators S1 through S4 is 1896 MHz, resonance frequencies of series resonator S2 through S4 are 1886 MHz, and the resonance frequency of one of four series resonators S1 through S4 is different from those of the others. In addition, the filter C has a configuration in which the resonance frequency of P1 is 1834 MHz, the resonance frequency of P2 is 1843 MHz, the resonance frequency of P3 is 1838 MHz in parallel resonators P1 through P3, and thus resonance frequencies of parallel resonators P1 through P3 are all different from each other.

FIG. 10A illustrates bandpass characteristics of filters, FIG. 10B illustrates return loss characteristics at the output terminal, and FIG. 10C illustrates return loss characteristics at the input terminal. In the filter C in which resonance frequencies of resonators are made to have different values by the patterning of the second mass load film 24, the matching states at the input terminal and the output terminal are improved compared to the filter B in which resonance frequencies of series resonators S1 through S4 are equal to each other and resonance frequencies of parallel resonators P1 through P3 are equal to each other.

As described above, according to the acoustic wave filter in accordance with the first embodiment, it is possible to make resonance frequencies of piezoelectric thin film resonators in the ladder filter have different values by changing the area (coverage rate) of the second mass load film 24 provided to the resonance region 40. As a result, it is possible to achieve the bandwidth widening and improvement of the matching of the acoustic wave filter using the temperature compensation film 16 such as SiO₂. In addition, in a case where the resonance frequency is shifted from the desired value due to the variability of the film thickness of the temperature compensation film 16, it is possible to correct the shift of the resonance frequency by changing the area (coverage rate) of the second mass load film 24 as described in FIG. 9B. As a result, it is possible to suppress the variability of the frequency.

As a method to control resonance frequencies of resonators in the acoustic wave filter, a method changing the film thickness of a part of the multilayered film 30 in each resonator, a method providing an extra mass load film, or the like is considered. However, in above described methods, as the number of resonance frequencies made to have different values increases, the production process (film forming process, photolithography process, etching process and the like) becomes complicated, and the production cost of the device increases. On the other hand, as described in the first embodiment, in the method which changes the coverage rate (area) by the patterning of the second mass load film 24, the film thickness of the second mass load film 24 can be the same in all resonators. In addition, as the change of the patterning (coverage rate) is relatively easily executed, it is possible to execute the adjustment of the resonance frequency easily compared to other methods, and there is an advantage in the production process.

### Second Embodiment

The second embodiment is an embodiment in which the configuration of the ladder filter is changed.

FIG. 11 is a circuit diagram illustrating a configuration of an acoustic wave filter in accordance with a second embodiment (filter D). The circuit configuration of the acoustic wave filter in accordance with the second embodiment is basically the same as that of the acoustic wave filter in accordance with the first embodiment (FIG. 1), except that in addition to inductors L1 and L2, an inductor L3, one end of which is connected to ground, is connected between the input terminal In and the series resonator S4. The structure of the piezoelectric thin film resonator which constitutes the ladder filter is the same as that of the first embodiment (FIG. 7, FIG. 8). Resonance frequencies of resonators are shown in columns of filter D in FIG. 5.

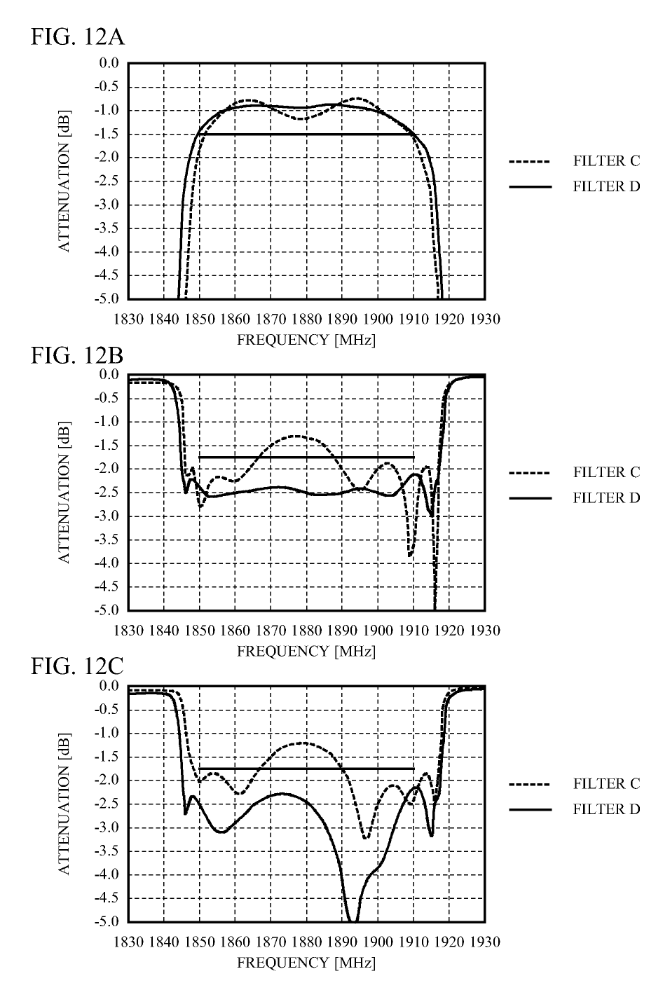

FIGS. 12A through 12C are graphs illustrating a comparison of bandpass characteristics between the acoustic wave filter in accordance with the second embodiment (filter D) and the acoustic wave filter in accordance with the first embodiment (filter C). FIG. 12A shows bandpass characteristics of filters, FIG. 12B shows return loss characteristics at the output terminal, and FIG. 12C shows return loss characteristics at the input terminal. The bandwidth of the filter is widened by adding the inductor L3 (FIG. 12A), and the matching states at the input terminal and the output terminal are improved (FIGS. 12B and 12C).

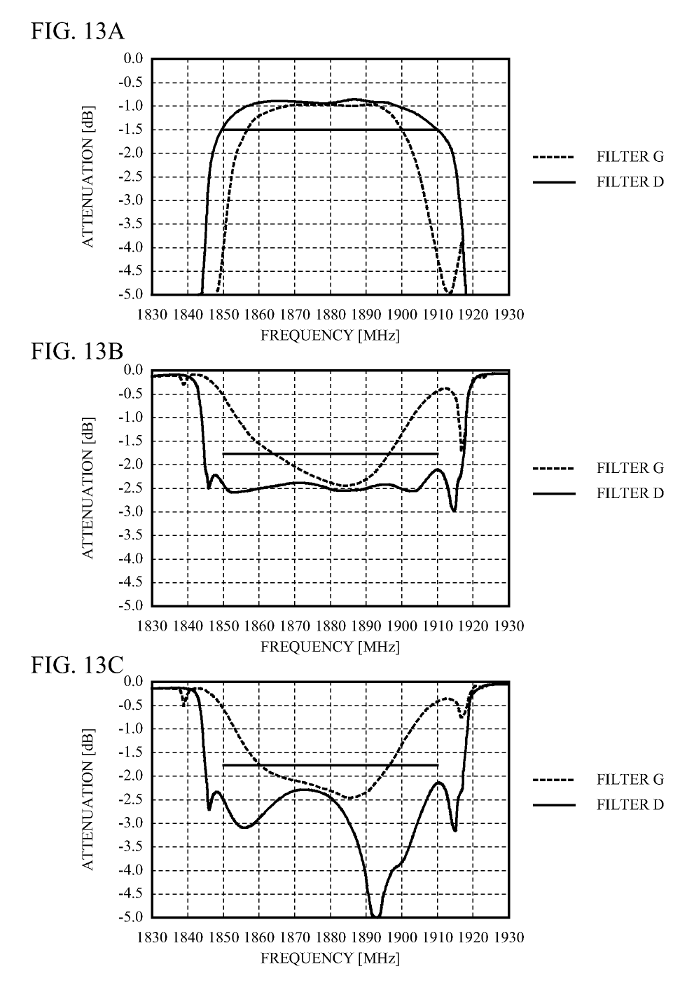

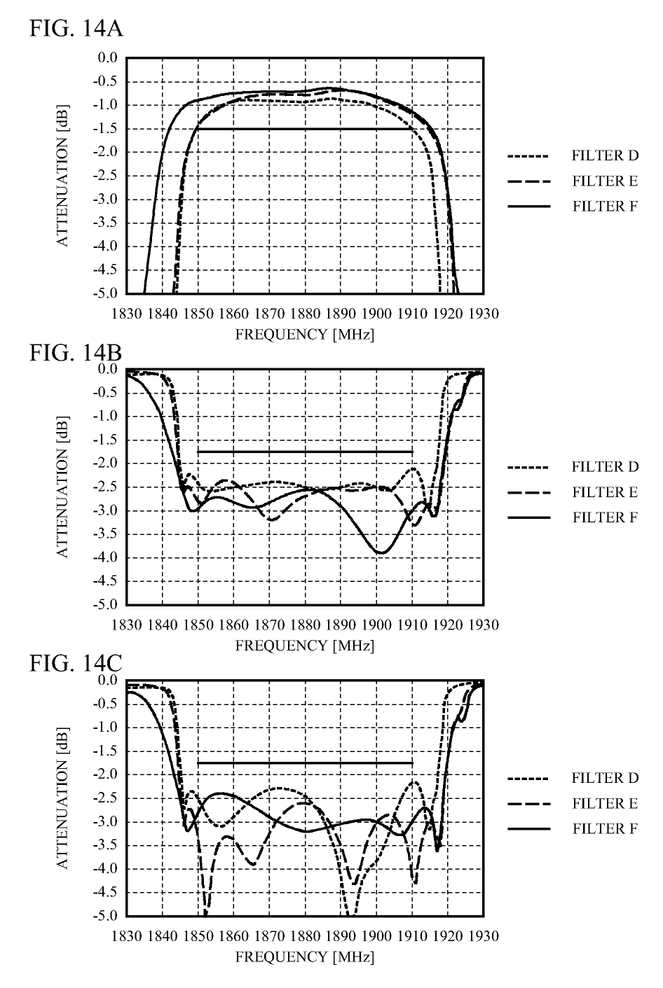

FIGS. 13A through 13C are graphs illustrating a comparison of band characteristics between the acoustic wave filter in accordance with the second embodiment (filter D) and the acoustic wave filter in accordance with the comparative example (filter G). As illustrated in FIG. 5, the circuit configuration of the filter G is the same as that of the filter D (FIG. 11), and resonance frequencies of series resonators S1 through S4 are equal to each other at 1893 MHz, and resonance frequencies of parallel resonators P1 through P3 are equal to each other at 1834 MHz.

FIG. 13A shows bandpass characteristics of filters, FIG. 13B shows return loss characteristics at the output terminal, and FIG. 13C shows return loss characteristics at the input terminal. The bandwidth of the filter is greatly widened by making resonance frequencies of resonators have different values like the filter D in accordance with the second embodiment (FIG. 13A), and the matching states at the input terminal and the output terminal are also improved (FIGS. 13B and 13C).

As described above, according to the acoustic wave filter in accordance with the second embodiment, it becomes possible to further widen the bandwidth of the filter and increase the effect of improving the matching by providing the inductor L3 between the input terminal In and a ground. In addition, in filters where the inductor L3 is provided in the same manner, it is possible to achieve the further bandwidth widening and improvement of the matching of the filter by making resonance frequencies of piezoelectric thin film resonators have different values.

### Third Embodiment

A third embodiment is an embodiment using a piezoelectric thin film resonator in which the piezoelectricity of the piezoelectric film is improved.

A circuit configuration of acoustic wave filters in accordance with the third embodiment (filters E, F) is the same as that of the second embodiment (FIG. 11), and a structure of the piezoelectric thin film resonator constituting the ladder filter is the same as those of the first and second embodiments (FIG. 7, FIG. 8). Different from the first and second embodiments, an element to increase the piezoelectric constant (e33) is added to piezoelectric films (the first piezoelectric film 14a and the second piezoelectric film 14b) of the piezoelectric thin film resonator. As the element to increase the piezoelectric constant, alkali earth metal (scandium (Sc) and the like), rare-earth metal (erbium (Er) and the like) can be used for example.

In the piezoelectric thin film resonator in accordance with the comparative example and first and second embodiments, the piezoelectric constant (e33) of the piezoelectric film is set to 1.54 [C/m₂]. In acoustic wave filters in accordance with the third embodiment, the piezoelectric constant (e33) is increased by 10% and is set to 1.69 [C/m₂] in the filter E, and the piezoelectric constant (e33) is increased by 20% and is set to 1.85 [C/m₂] in the filter F.

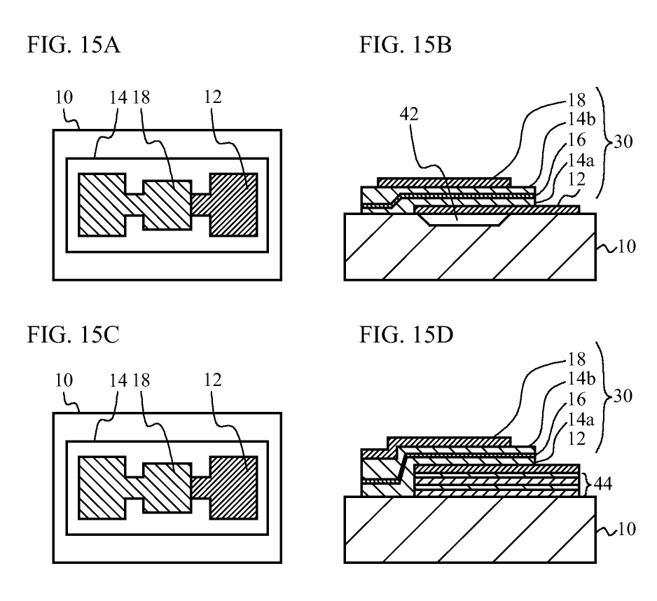

FIGS. 14A through 14C are graphs illustrating a comparison of band characteristics between acoustic wave filters in accordance with the third embodiment (filters E, F) and the acoustic wave filter in accordance with the second embodiment (filter D). FIG. 14A shows bandpass characteristics of filters, FIG. 14B shows return loss characteristics at the output terminal, and FIG. 14C shows return loss characteristics at the input terminal. As illustrated, as the piezoelectricity of piezoelectric films (14a, 14b) is increased, the bandwidth is greatly widened (FIG. 14A), and the matching states at the input terminal and the output terminal are improved (FIGS. 14B, 14C).

According to the acoustic wave filter in accordance with the third embodiment, it is possible to further widen the bandwidth of the filter and further increase the effect of improving the matching of the filter by increasing the piezoelectricity of the piezoelectric film in the piezoelectric thin film resonator. In addition, in the acoustic wave filter in which the piezoelectricity of the piezoelectric film is increased in the same manner, it is possible to achieve the further bandwidth widening and improvement of the matching of the filter by making resonance frequencies of piezoelectric thin film resonators have different values.

In first through third embodiment, the temperature compensation film 16 is formed between the first piezoelectric film 14a and the second piezoelectric film 14b, but the temperature compensation film 16 may be formed in other places as long as it is located in the resonance region 40 where the lower electrode 12 and the upper electrode 18 face each other. However, it is preferable that at least a part of the temperature compensation film 16 is located between the lower electrode 12 and the upper electrode 18.

In addition, in first through third embodiments, the second mass load film 24 for the frequency control is formed between the upper electrode 18 and the frequency adjusting film 20, but the second mass load film 24 may be formed in other places as long as it is located in the resonance region 40. Moreover, the second mass load film 24 may be formed on more than two different layers. The second mass load film 24 has a different shape from that of the resonance region 40 by the patterning. In first through third embodiments, descriptions were given of the example in which periodical patterns are formed, but the pattern may be un-periodical pattern. In addition, in first through third embodiments, descriptions were given of the example in which both dot patterns 60 and line patterns 62 are formed, but it may be possible to form only dot patterns 60 without forming line patterns 62 for example.

In addition, in first through third embodiments, descriptions were given by using the piezoelectric thin film resonator in which the dome-shaped space 42 is formed below the lower electrode 12 as the example, but the structure of the piezoelectric thin film resonator may be others.

FIG. 15A through 15D are schematic views of piezoelectric thin film resonators in accordance with modified embodiments of first through third embodiments. In this illustration, only the substrate 10, the lower electrode 12, the first piezoelectric film 14a, the temperature compensation film 16, the second piezoelectric film 14b, and the upper electrode 18 are illustrated, and the illustration of other stacked films (mass load film and frequency adjusting film) is omitted. However, the structure of the multilayered film 30 are the same as those of first through third embodiments, and includes the second mass load film 24 capable of controlling the resonance frequency by the patterning.

FIG. 15B illustrates an example in which a sacrifice layer (not illustrated) is embedded to the concave portion (the space 42) provided to the surface of the substrate 10, and the lower electrode 12 which is formed on it is made flat. The piezoelectric thin film resonator having the present structure can be obtained by removing the sacrifice layer by the wet etching after forming the multilayered film 30, including the lower electrode 12, on the flat surfaces of the substrate 10 and the sacrifice layer. As described, the shape of the space 42 may be a shape other than the dome.

FIG. 15D is a SMR (Solid Mounted Resonator) type resonator using an acoustic reflection film 44 instead of forming the space below the lower electrode 12. The acoustic reflection film 44 is formed by stacking alternately a film of which acoustic impedance is high and a film of which acoustic impedance is low with a film thickness of λ/4 (λ is a wave length of acoustic wave). The piezoelectric thin film resonator having the present structure can be obtained by forming the acoustic reflection film on the surface of the substrate 10, and forming the multilayered film 30, including the lower electrode 12, thereon. As described, the structure in which the space is not formed below the lower electrode 12 can be adopted.

In first through third embodiments (FIG. 1, FIG. 11), inductors (L2, L3) which are connected between the input terminal In or the output terminal Out and a ground are referred to as first inductors, and the inductor (L1) which is connected between parallel resonators P1 through P3 and a ground is referred to as a second inductor. It is sufficient if first inductors are connected to at least one of the input terminal In side and the output terminal Out side, but it is more preferable that first inductors are connected to both of the input terminal In side and the output terminal Out side.

In first through third embodiments, descriptions were given by using a ladder-type filter (FIG. 1, FIG. 11) as an example, but the configuration of the filter using piezoelectric thin film resonators in accordance with first through third embodiments is not limited to above specific embodiments. For example, in FIG. 1 and FIG. 11, one ends of parallel resonators P1 through P3 are unified and connected to ground via the inductor L1, but parallel resonators P1 through P3 may be provided with respective inductors and unified. In addition, in first through third embodiments, the number of series resonators is four (S1 through S4) and the number of parallel resonators is three (P1 through P3), but the number of series resonators and the number of parallel resonators may be other numbers. In this case, it is possible to take a configuration in which more than two parallel resonators out of parallel resonators are unified and connected to ground via an inductor. In addition, a configuration of the acoustic wave filter may be other than the ladder-type filter as described hereinafter.

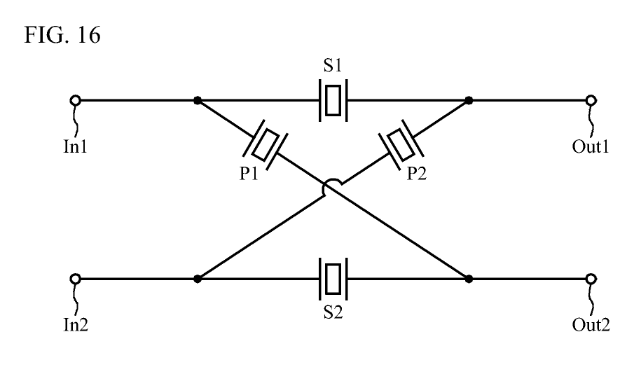

FIG. 16 is a circuit diagram illustrating a configuration of a lattice-type acoustic wave filter in accordance with a modified embodiment of first through third embodiments. The lattice-type acoustic wave filter is provided with two input terminals (a first input terminal In1 and a second input terminal In2), and two output terminals (a first output terminal Out1 and a second output terminal Out2). The series resonator S1 is connected between the first input terminal In1 and the first output terminal Out1, and the series resonator S2 is connected between the second input terminal In2 and the second output terminal Out2. In addition, the parallel resonator P1 is connected between the first input terminal In1 and the second output terminal Out2, and the parallel resonator P2 is connected between the second input terminal In2 and the first output terminal Out1.

Series resonators S1 and S2 and parallel resonators P1 and P2 are piezoelectric thin film resonators having a same structure as those of first through third embodiments, and includes the temperature compensation film 16 and the second mass load film 24. Therefore, as same with the first through third embodiments, it is possible to achieve the bandwidth widening and improvement of the matching of the filter by making resonance frequencies of series resonators S1 and S2 have different values from each other and making resonance frequencies of parallel resonators P1 and P2 have different values from each other by changing the pattern of the second mass load film 24. As described above, piezoelectric thin film resonators in accordance with first through third embodiments can be adopted to filters other than the ladder-type filter.

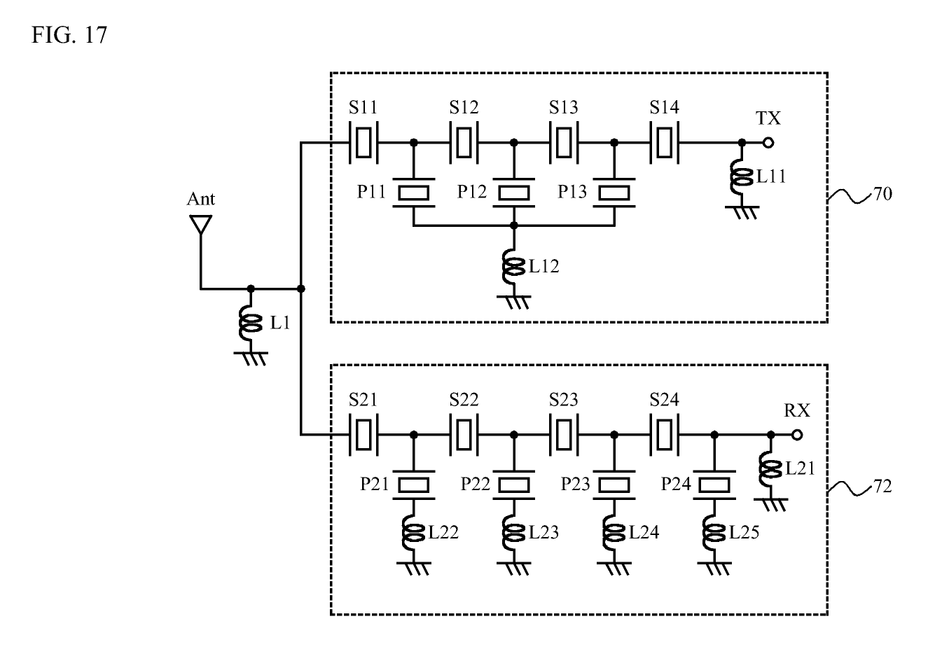

FIG. 17 is a circuit diagram illustrating a configuration of a duplexer using the acoustic wave filter in accordance with first through third embodiments. The duplexer is provided with a transmission terminal TX, a reception terminal RX, and an antenna terminal Ant common to those. A transmission filter 70 is located between the transmission terminal TX and the antenna terminal Ant, and a reception filter 72 is located between the reception terminal RX and the antenna terminal Ant.

The configuration of the transmission filter 70 is the same as that of the filter described in the second embodiment (FIG. 11), and includes four series resonators (S11 through S14), three parallel resonators (P11 through P13), and inductors (L11 and L12). However, the inductor L1 on the antenna terminal Ant side is common to the transmission filter 70 and the reception filter 72. This achieves the matching function that is the same as that of the inductor L2 on the output terminal Out side in FIG. 1 and FIG. 11.

The reception filter 72 includes four series resonators (S21 through S24), four parallel resonators (P21 through P24), and inductors (L21 through L25). Different from the transmission filter 70, ground sides of parallel resonators P21 through P24 are not unified, and connected to ground via respective inductors L22 through L25. In addition, the inductor L1 on the antenna terminal Ant side is common to the transmission filter 70.

In the duplexer having the configuration illustrated in FIG. 16, it is possible to achieve the bandwidth widening and improvement of the matching by making resonance frequencies of series resonators have different values from each other and making resonance frequencies of parallel resonators have different values from each other by using the piezoelectric thin film resonator in accordance with first through third embodiments.

In the above described duplexer, the inductor L1 is located between the antenna terminal Ant and a ground as the element for the matching, but the configuration of the element for the matching is not limited to the above. For example, it is possible to use a matching circuit comprised of multiple elements instead of the inductor L1. In addition, in the above described duplexer, both of the transmission filter 70 and the reception filter 72 have a circuit configuration that is the same as that of the second embodiment (FIG. 11), but only one of them may have the same circuit configuration as that of the second embodiment. In addition, one of the transmission filter 70 and the reception filter 72 may be a SAW (Surface Acoustic Wave) filter. When the reception terminal is a balanced output for example, it is considered to use a DMS (Double Mode Saw) filter as the SAW filter.

Although the embodiments of the present invention have been described in detail, it should be understood that the various change, substitutions, and alterations could be made hereto without departing from the spirit and scope of the claimed invention.

What is claimed is:

1. An acoustic wave filter including piezoelectric thin film resonators, wherein
at least two of the piezoelectric thin film resonators comprise:
a substrate;
a piezoelectric film located on the substrate;
a lower electrode and an upper electrode located across at least a part of the piezoelectric film;
a mass load film for a frequency control which is located in a resonance region in which the lower electrode and the upper electrode face each other, and has a shape different from that of the resonance region; and
a temperature compensation film that has a temperature coefficient of an elastic constant that is opposite in sign to a temperature coefficient of an elastic constant of the piezoelectric film, at least a part of the temperature compensation film being located between the lower electrode and the upper electrode in the resonance region, and
areas of mass load films of said at least two of the piezoelectric thin film resonators are different from each other.

2. The acoustic wave filter according to claim 1, wherein
piezoelectric thin film resonators out of the piezoelectric thin film resonators are located in a series arm of the acoustic wave filter and piezoelectric thin film resonators out of the piezoelectric thin film resonators are located in a parallel arm of the acoustic wave filter, and
the piezoelectric thin film resonators located in at least one of the series arm and the parallel arm include the two piezoelectric thin film resonators of which areas of mass load films are different from each other.

3. The acoustic wave filter according to claim 1, wherein the temperature compensation film mainly includes oxide silicon.

4. The acoustic wave filter according to claim 1, wherein the piezoelectric film is made of aluminum nitride.

5. The acoustic wave filter according to claim 4, wherein the aluminum nitride includes an element which increases a piezoelectric constant.

6. The acoustic wave filter according to claim 1, further comprising:
an input terminal and an output terminal; and
a first inductor which is connected at least between the input terminal and a ground, or between the output terminal and a ground.

7. The acoustic wave filter according to claim 1, further comprising a second inductor which is connected between the piezoelectric thin film resonators located in the parallel arm and a ground.

8. The acoustic wave filter according to claim 1, wherein a fractional bandwidth is equal to or more than −0.041*T+2.17 [%] when a temperature coefficient of frequency at an edge of a passband in the acoustic wave filter is expressed with T [ppm/° C.].

9. A duplexer including a transmission filter and a reception filter, wherein at least one of the transmission filter and the reception filter is provided with the acoustic wave filter according to claim 1.
